(19) United States
(12) Patent Application Publication
(10) Pub. No.: US 2012/0114910 A1
(43) Pub. Date: May 10, 2012

(54) FLEXIBLE GAS BARRIER FILM, METHOD FOR PREPARING THE SAME, AND FLEXIBLE DISPLAY DEVICE USING THE SAME

(75) Inventors: Byeong Kwon JU, Seoul (KR); Jin-Hwan CHOI, Seoul (KR); Young-Wook PARK, Seoul (KR); Tae Hyun PARK, Seoul (KR); Ki-Young DONG, Seoul (KR)

(73) Assignee: KOREA University Research and Business Foundation, Seoul (KR)

(21) Appl. No.: 12/943,546

(22) Filed: Nov. 10, 2010

(51) Int. Cl. B32B 3/10; C23C 14/34; B41F 33/00; B05D 5/00; G03F 7/20

(52) U.S. Cl. 428/172; 427/256; 430/322; 430/296; 101/483; 204/192.1

(57) ABSTRACT

The present invention provides a flexible gas barrier film including: a transparent base film; and a hydrophobic pattern layer formed on the base film. The flexible gas barrier film is capable of maximizing hydrophobicity and effectively reducing water vapor permeability by patterning the hydrophobic layer.

### BACKGROUND OF THE INVENTION

1. Field of the Invention

The present invention relates to a gas barrier film for use in a flexible display substrate and a method for preparing the same, and more particularly, to a gas barrier film which includes a transparent base film and a hydrophobic pattern layer formed on the base film and is capable of maximizing hydrophobicity and effectively reducing water vapor permeability by patterning the hydrophobic pattern layer, and a method for preparing the same.

2. Description of the Related Art

A flexible display is being now appreciated as the next generation technology for the field of flat displays because of its flexibility and its transformability into a roll with its high display ability maintained and is thus under active worldwide research and development. As it is not easy to implement a substrate to be used for such a flexible display using an existing rigid glass substrate, a transparent plastic substrate is being now used for the flexible display substrate. However, while such a glass substrate can provide effective prevention of water and oxygen from permeating into the substrate, the plastic substrate has lower gas barrier ability because of it larger permeability of water and oxygen than the glass substrate. Use of a substrate having lower gas barrier ability may contribute to shorter lifespan due to reaction with organic substance permeating into the substrate and degradation of display quality due to deterioration of elements by permeation of vapor or air into the substrate. This promotes use of a technique to coat a passivation film made of ceramics or the like on a plastic substrate or film. Unfortunately, this technique has a problem of diffusion of water into a ceramics layer or the like due to small pin holes or cracks. To avoid this problem, there have been developed techniques for coating material such as polymeric acryl resin, melamine resin or the like on a ceramics passivation film or preventing permeation of water using a multi-layered structure. FIG. 1 shows a structure with a hydrophobic layer formed on a transparent base film.

Japanese Patent Application Laid-Open No. Sho53-12953 discloses a gas barrier film with silicon oxide deposited on a plastic film base, Japanese Patent Application Laid-Open No. Sho58-217344 discloses a gas barrier film with aluminum oxide deposited on a plastic film, and Japanese Patent Application Laid-Open No. 2002-100469 discloses a gas barrier film with a silicon oxy-nitride film formed on a plastic film base.

However, although these disclosed gas barrier films may act to decrease a diffusion speed of water in a passivation film or enlarge a diffusion path, they have demerits of insufficient gas barrier performance due to excess of water vapor permeability over 0.1 g/m² day and impossibility of prevention of a minute amount of water from permeating into elements with temporal variation of the films. On the other hand, there has been proposed a method for forming a multi-layered gas barrier structure for sufficient gas barrier performance; however, this method also has a problem of poor productivity due to increased thickness of a gas barrier film and generation of cracks due to tension occurring in a barrier layer.

In addition, Korean Patent No. 550377 discloses a structure with a hard coating film made of parylene. However, this disclosed structure also has a disadvantage in that a parylene layer has to be deposited with a thickness of 5 μm or more in order to achieve sufficient gas barrier ability.

### SUMMARY OF THE INVENTION

Accordingly, it is an object of the present invention to provide a flexible gas barrier film which is capable of maximizing hydrophobicity and increasing a water repulsive force by patterning a hydrophobic layer.

It is another object of the present invention to provide a flexible gas barrier film which is capable of further reducing water vapor permeability by discharging water from a hydrophobic surface to an outer hydrophilic region by forming a patterned hydrophilic layer on the patterned hydrophobic layer.

It is still another object of the present invention to provide a flexible gas barrier film which is capable of effectively reducing water vapor permeability by controlling a surface tension of existing barrier material, without increasing production costs.

It is yet still another object of the present invention to provide a flexible gas barrier film with high gas barrier ability which can be applied to flexible display devices, touch panels, solar cells, and various kinds of packing materials and so on.

It is yet still another object of the present invention to provide a method for preparing a flexible gas barrier film easily without adding complicated processes.

It is yet still another object of the present invention to provide a flexible display device with high durability and reliability using the above flexible gas barrier film as a substrate.

To achieve the above objects, according to an aspect of the invention, there is provided a flexible gas barrier film including: a transparent base film; and a hydrophobic pattern layer formed on the base film.

In one implementation, the hydrophobic pattern layer may be made of polymer whose surface tension is 1 to 40 mN/m.

In one implementation, the hydrophobic pattern layer may have an embossed pattern.

In one implementation, the hydrophobic pattern layer may have a pattern width of 1 to 500 nm and a distance between centers of pattern may be 0.1 to 10 times as large as the pattern width.

In one implementation, a water vapor permeability of the gas barrier film may be less than 0.08 g/m² day.

In one implementation, a hydrophilic pattern layer may be formed on the hydrophobic pattern layer.

In one implementation, the hydrophilic pattern layer may be made of Si-based material whose surface tension is 70 to 100 mN/m.

In one implementation, the hydrophilic pattern layer has an embossed pattern.

In one implementation, the hydrophilic pattern layer may be formed in discontinuity.

In one implementation, the hydrophilic pattern layer may have a pattern width of 0.1 to 1 mm and a distance between centers of pattern may be 0.1 to 10 times as large as the pattern width.

In one implementation, a water vapor permeability of the gas barrier film may be less than 1×10⁻³ g/m2 day.

In one implementation, an inorganic layer made of oxide, nitride, carbide, oxy-nitride, oxy-carbide, nitro-carbide or oxy-nitro-carbide containing one or more metal selected from a group consisting of Si, Al, In, Sn, Zn, Ti, Cu, Ce and Ta may be formed on at least one surface of the transparent base film.

In one implementation, the transparent base film may be made of one or more selected from a group consisting of polyethylenenaphthalate, (meta)acrylate-based resin, polyester-based resin, styrene-based resin, transparent fluoro resin, polyimide-based resin, polyamide-based resin, polyetherimide-based resin, celluloseacylate-based resin, polyurethane resin, polyetheretherketone resin, polycarbonate resin, alicyclic polyolefine resin, polyalylate resin, polyethersulfone resin, polysulfone resin, cycloolefine copolymer, fluorene-ring modified polycarbonate resin, polyethylene and cyclic modified polycarbonate resin.

In one implementation, the hydrophobic pattern layer may be made of one or more selected from a group consisting of acryl resin, parylene and melamine

In one implementation, the hydrophilic pattern layer may be made of one selected from a group consisting of SiO₂, SiO and TiO₂.

According to another aspect of the invention, there is provided a flexible displace device which uses the above flexible gas barrier film as a substrate.

According to still another aspect of the invention, there is provided a method for preparing a flexible gas barrier film, the method including: forming a hydrophobic layer by coating or depositing polymer whose surface tension is 1 to 40 mN/m on a surface of a transparent base film; and forming a hydrophobic pattern layer by patterning the hydrophobic layer.

In one implementation, the method may further include patterning a hydrophilic layer whose surface tension is 70 to 100 mN/m on the hydrophobic pattern layer.

In one implementation, the hydrophobic layer may be patterned using ultraviolet imprinting, photolithography, micro contact printing, ink-jet printing, or screen printing

In one implementation, the hydrophilic layer may be patterned using E-beam evaporation using a mask, sputtering, solution coating, thermal evaporation or printing.

The present invention provides a flexible gas barrier film which is capable of effectively reducing a water vapor permeability by controlling a surface tension of existing barrier material, without increasing production costs, and a flexible gas barrier film with high gas barrier ability which can be applied to flexible display devices, touch panels, solar cells, various kinds of packing materials and so on. In addition, the present invention provides a flexible display device with high durability and reliability using the above flexible gas barrier film as a substrate

Moreover, the present invention provides a method for preparing a flexible gas barrier film easily without adding complicated processes.

### BRIEF DESCRIPTION OF THE DRAWINGS

The above and/or other aspects and advantages of the present invention will become apparent and more readily appreciated from the following description of the embodiments, taken in conjunction with the accompanying drawings of which:

FIG. 1 shows a structure with a hydrophobic layer formed on a transparent base film;

FIG. 2 is a schematic sectional view of a flexible gas barrier film with a hydrophobic pattern layer formed on a transparent base film;

FIG. 3 is a schematic sectional view of a flexible gas barrier film with a hydrophilic pattern layer formed on a hydrophobic pattern layer;

FIG. 4 shows one embodiment of a flexible gas barrier film with an inorganic layer formed between a hydrophobic pattern layer and a transparent base film;

FIG. 5 shows a process of forming a hydrophobic pattern layer according to Embodiment 1;

FIG. 6 is a schematic view showing a flexible gas barrier film with a hydrophobic pattern layer formed thereon according to Embodiment 1;

FIG. 7 shows a process of forming a hydrophilic pattern layer according to Embodiment 3;

FIG. 8 is a schematic view showing a flexible gas barrier film with a hydrophilic pattern layer formed thereon according to Embodiment 3;

FIG. 9 is a graph showing comparison in water vapor permeability with time between Embodiment 1 and Comparative Example 1; and

FIG. 10 is a graph showing comparison in water vapor permeability with time between Embodiment 2 and Embodiment 3.

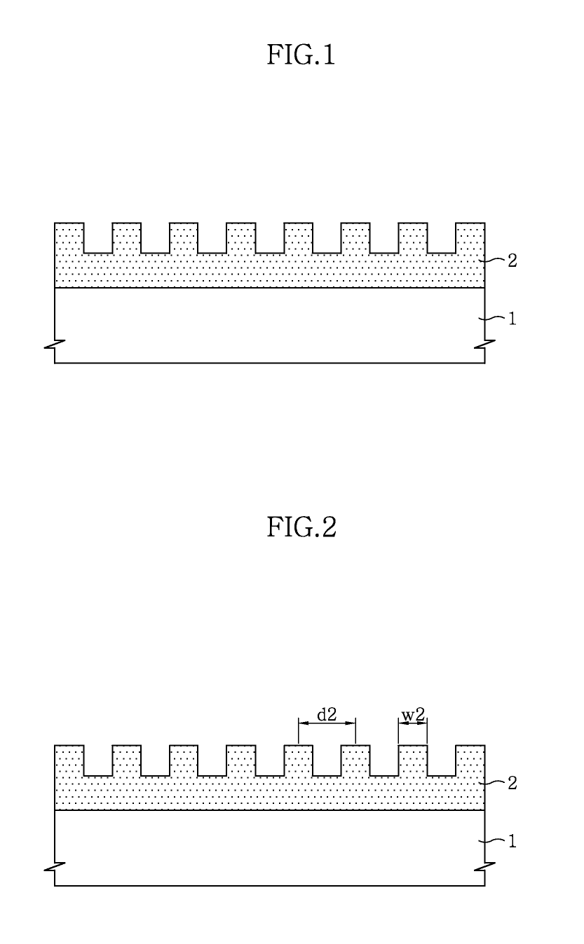

### DETAILED DESCRIPTION OF THE PREFERRED EMBODIMENT

Flexible Gas Barrier Film

In one implementation, a flexible gas barrier film according to the present invention includes a transparent base film; and a hydrophobic pattern layer formed on the base film. In this implementation, a water vapor permeability of the gas barrier film with the hydrophobic pattern layer formed on the base film is less than 0.08 g/m² day, preferably less than 0.065 g/m² day.

In another implementation, an inorganic layer may be additionally formed between the transparent base film and the hydrophobic pattern layer.

In still another implementation, an inorganic layer may be formed on both sides of the transparent base film and the hydrophobic pattern layer may be formed on the inorganic layer.

In still another implementation, a hydrophilic pattern layer may be additionally formed on the hydrophobic pattern layer. A water vapor permeability of the gas barrier film with both of the hydrophobic and hydrophilic pattern layers formed thereon may be less than 1×10⁻³ g/m² day, preferably less than 1×10⁻⁴ g/m² day, more preferably less than 1×10⁻⁵ g/m² day.

Transparent Base Film

A flexible plastic film may be used as the flexible gas barrier film and its material, thickness and the like may be appropriately selected for its use purpose with no particular limitation thereto.

In an implementation, the transparent base film may be made of polyethylenenaphthalate, (meta)acrylate-based resin, polyester-based resin, styrene-based resin, transparent fluoro resin, polyimide-based resin, polyamide-based resin, polyetherimide-based resin, celluloseacylate-based resin, polyurethane resin, polyetheretherketone resin, polycarbonate resin, alicyclic polyolefine resin, polyalylate resin, polyethersulfone resin, polysulfone resin, cycloolefine copolymer, fluorene-ring modified polycarbonate resin, polyethylene, cyclic modified polycarbonate resin, solely or in a combination thereof.

If the transparent base film is used for a display substrate in an organic EL (electroluminescent) device or the like, the film may employ transparent heat-resistant material having its glass transition temperature (Tg) which is more than 100° C., preferably more than 150° C., more preferably more than 200° C., most preferably more than 250° C., and its total light transmittance which is more than 80%, preferably more than 85%, more preferably more than 90%. In an implementation, the transparent base film used for the display substrate may be made of polyethylenenaphthalate (PEN), polycarbonate (PC), alicyclic polyolefine, polyalylate, polyethersulfone (PES), polysulfone (PSF), cycloolefine copolymer (COC), polyimide, fluorene-ring modified polycarbonate (BCF-PC), cyclic modified polycarbonate (IP-PC), acryloyl compound, etc.

The thickness of the transparent base film may be selected according to its usage, typically ranging from 1 to 1,000 μm with no limitation thereto. In an implementation, the thickness may be selected to be 10 to 300 μm. In another implementation, the thickness may be selected to be 100 to 400 μm. In still another implementation, the thickness may be selected to be 500 to 800 μm.

Hydrophobic Pattern Layer

The hydrophobic pattern layer employs essentially-hydrophobic material whose surface tension in a solid state is smaller than a water surface tension even before it is patterned.

In an implementation, the hydrophobic pattern layer may be made of polymer having its post-cured surface tension which is less than 45 mN/m, preferably 0.1 to 40 mN/m, more preferably 0.5 to 35 mN/m, most preferably 1 to 30 mN/m.

In addition it may be desirable to use a surface contact angle of DI water which is more than 50°, preferably 50° to 135°, and a surface contact angle of Formamide which is more than 65°, preferably 70° to 125°.

In an implementation, the above-mentioned polymer may be solution-processed and may include, but is not limited to, acryl resin, parylene, melamine or the like.

FIG. 2 shows an example flexible gas barrier film with a hydrophobic pattern layer 2 formed on a transparent base film 1. As shown in FIG. 2, the hydrophobic pattern layer 2 of this invention is formed with repetitive pattern on the transparent base film 1. Preferably, the pattern is an embossed pattern. However, the shape of pattern may be circular, polygonal (triangular, rectangular, pentagonal, octagonal or the like) or any other shape with no particular limitation.

In an implementation, the hydrophobic pattern layer has a width w2 of pattern which is less than 10 μm. If the width w2 exceeds the value, it may be difficult to achieve an effective gas barrier since the width is larger than size of gas particles. The width w2 of pattern is preferably 1 to 500 nm, more preferably 1 to 350 nm, most preferably 1 to 250 nm.

In addition, a distance d2 between one center of the pattern and another is 0.1 to 10 times, preferably 1 to 5 times, more preferably 1.2 to 3.5 times, most preferably 1.5 to 2.5 times, as large as the pattern width w2. This range may maximize a gas barrier effect.

The thickness of the hydrophobic pattern layer is not particularly limited but is 100 to 3,000 nm, preferably 200 to 2,000 nm, more preferably 250 to 1,500 nm.

As shown in FIG. 2, the hydrophobic pattern layer 2 of this invention may include a continuous surface formed on a contact surface with the transparent base film and a discontinuous pattern formed on the opposite surface.

The height of the pattern is not particularly limited but is 50 to 2,500 nm, preferably 100 to 1,500 nm, more preferably 150 to 1,000 nm. In an implementation, the height of the pattern may be 200 to 500 nm.

When a pattern is formed in the hydrophobic pattern layer in this manner, water repulsive force increases to lower a surface tension by 75 to 99% or more, thereby significantly lowering a water vapor permeability. In an implementation, the surface tension of the patterned hydrophobic layer is less than 15 mN/m, preferably 15 0.01 to 10 mN/m, more preferably 0.1 to 7.5 mN/m. A surface contact angle of D1 water is more than 100°, preferably 110 to 140° and a surface contact angle of Formamide is more than 90°, preferably 100 to 130°.

A method for forming the hydrophobic pattern layer is not particularly limited. An example of this method may include one or more methods for forming a pattern using ultraviolet radiation in consideration of room temperature process, invariability of pattern and chemical stability after process and the like. In an implementation, the hydrophobic pattern layer may be formed using ultraviolet imprinting, photolithography or the like.

Hydrophilic Pattern Layer

In other implementations of the present invention, a hydrophobic pattern layer may be additionally formed on the hydrophobic pattern layer.

The hydrophilic pattern layer may employ essentially-hydrophilic material whose surface tension in a solid state is larger than a water surface tension.

In an implementation, the hydrophobic pattern layer may be made of inorganic material, preferably Si-based material, having its surface tension which is more than 60 mN/m, preferably 65 to 120 mN/m, more preferably 70 to 100 mN/m.

In addition it may be desirable to use a surface contact angle of DI water which is less than 15°, preferably 0.01° to 7°, and a surface contact angle of Formamide which is less than 10°, preferably 0.01° to 7°.

In an implementation, the hydrophilic pattern layer may be made of SiO₂, SiO, TiO₂ or any other similar material.

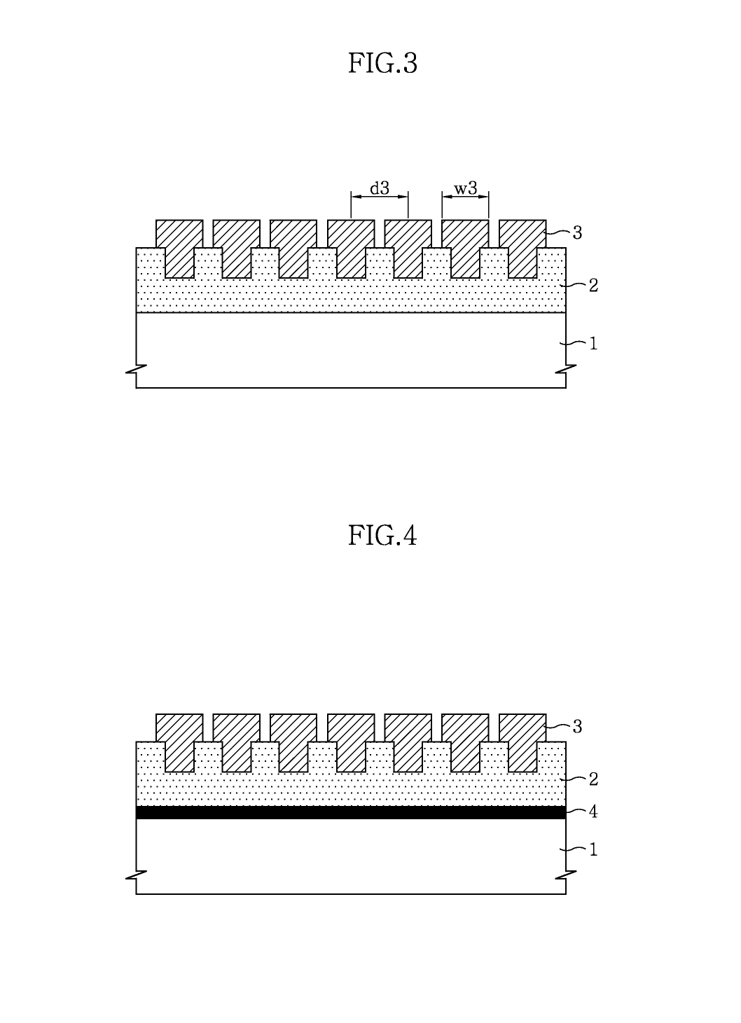

FIG. 3 shows an example flexible gas barrier film with a hydrophilic pattern layer 3 formed on the hydrophobic pattern layer 2. As shown in FIG. 3, the hydrophilic pattern layer 3 of this invention is formed with repetitive pattern on the hydrophobic pattern layer 2. Preferably, the pattern is an embossed pattern. However, the shape of pattern may be circular, polygonal (triangular, rectangular, pentagonal, octagonal or the like) or any other shape with no particular limitation. Preferably, the hydrophilic pattern layer may be formed in discontinuity. As used herein, the term “discontinuity” refers to disconnection of one piece of the pattern from another.

In an implementation, the hydrophilic pattern layer has a width w3 of pattern which is less than 10 μm. If the width w3 exceeds the value, it may be difficult to achieve an effective gas barrier since the width is larger than size of gas particles. The width w3 of pattern is 0.05 to 2 mm, preferably 0.1 to 1 mm, more preferably 0.2 to 0.7 mm, most preferably 0.3 to 0.6 mm. This range may show a high gas barrier effect.

In addition, a distance d3 between one center of the pattern and another is 0.1 to 10 times, preferably 1 to 5 times, more preferably 1.2 to 3.5 times, most preferably 1.5 to 2.5 times, as large as the pattern width w3. This range may maximize a gas barrier effect.

The thickness of the hydrophilic pattern layer is not particularly limited but is 100 to 2,000 nm, preferably 200 to 1,000 nm, more preferably 250 to 700 nm, most preferably 300 to 600 nm.

When a pattern is formed in the hydrophilic pattern layer in this manner, hydrophilicity increases to further raise a surface tension. In addition, by forming the hydrophilic pattern layer on the hydrophobic pattern layer, water may be discharged from a hydrophobic surface into an outer hydrophilic region to absorb gas and/or water, thereby significantly lowering a water vapor permeability of the film.

A method for forming the hydrophilic pattern layer is not particularly limited. An example of this method may include shadow masking process, electron-beam evaporation using a mask, vacuum evaporation such as sputtering, solution coating such as printing, and the like in consideration of room temperature process, invariability of pattern and chemical stability after process, properties of selected material, size of pattern, and the like.

Inorganic Layer

In the present invention, an inorganic layer may be additionally formed on at least one surface of the transparent base film. FIG. 4 shows an example flexible gas barrier film with an inorganic layer 4 formed between the hydrophobic pattern layer 2 and the transparent base film 1. In another example, an inorganic layer may be formed on both sides of the transparent base film and a hydrophobic pattern layer may be formed on the inorganic layer.

In further example, two or more inorganic layers having different ingredients may be stacked on the transparent base film 1.

The inorganic layer may be made of, but is not limited to, oxide, nitride, carbide, oxy-nitride, oxy-carbide, nitro-carbide, oxy-nitro-carbide or the like containing one or more metal selected from a group consisting of Si, Al, In, Sn, Zn, Ti, Cu, Ce and Ta.

The inorganic layer may be formed using any of methods known in the art so as to be easily realized by those skilled in the art. In an implementation, the inorganic layer may be formed by, but is not limited to, coating, sputtering, vacuum evaporation, ion plating, plasma CVD or the like.

The thickness of the inorganic layer is not particularly limited but is 1 to 1,000 nm, preferably 10 to 500 nm, more preferably 50 to 350 nm.

Method for Preparing Flexible Gas Barrier Film

Another aspect of the present invention addresses a method of preparing a flexible gas barrier film. This method includes the steps of: forming a hydrophobic layer by coating or depositing a surface of a transparent base film with polymer having its surface tension of 1 to 40 mN/m; and forming a hydrophobic pattern layer by patterning the hydrophobic layer.

In an implementation, the hydrophobic layer may be formed by drop-casting, curing and coating polymer. The formed hydrophobic layer forms a continuous layer on the surface of the transparent base film and may be patterned to form the hydrophobic pattern layer.

The method for patterning the hydrophobic layer may include low temperature process, 3D patterning process, solution process and the like. Preferably, the hydrophobic layer may be patterned using ultraviolet imprinting, photolithography, micro contact printing, ink-jet printing, screen printing or any other suitable means.

In an implementation, the method may further include a step of forming an inorganic layer on the surface of the transparent base film before forming the hydrophobic layer. The inorganic may be formed on one or both sides of the transparent base film.

In addition, the method may further include a step of patterning a hydrophilic layer having its surface tension of 70 to 100 mN/m on the hydrophobic pattern layer.

In an implementation, the hydrophilic layer may be patterned using E-beam evaporation using a mask, sputtering, solution coating, thermal evaporation, printing or any other suitable means. The patterned hydrophilic layer may be discontinuously formed on the hydrophobic pattern layer.

Flexible Display Device

A further aspect of the present invention addresses a flexible display device. This flexible display device employs the flexible gas barrier film of the present invention as a substrate. The flexible display device according to the present invention may be applicable to transparent electrode substrate of LCD devices, substrates of organic EL devices, substrates for thin film transistor (TFT) image display devices, and other substrates known in the art.

In addition, the flexible gas barrier film of the present invention may be used as sealing films for touch panels and solar cell devices.

The present invention may be better understood when reading the following examples which are provided only for the purpose of illustration and are not intended to limit the scope of the invention defined by the annexed Claims.

### EXAMPLE 1

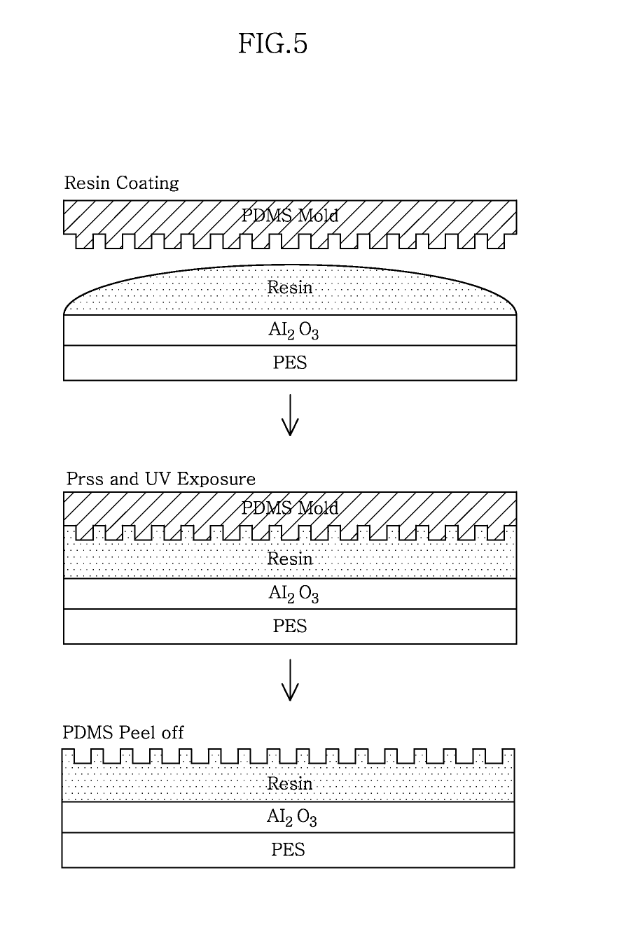

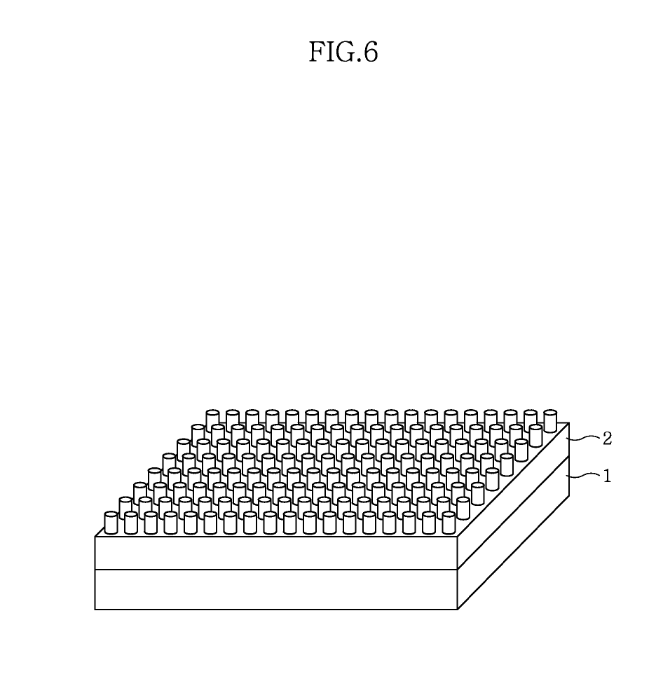

A 300 nm-thick Al₂O₃ (purity: 99.99%) layer was deposited as a gas barrier on a surface of a 200 μm-thick polyethersulfone (PES) substrate (glass transition temperature: 223° C., available from i-Components Ltd., Co.) using E-beam and a hydrophobic layer was formed by drop-casting Multi-cure 984-LVF (available from DYMAC Ltd., Co.) and then coating the Al₂O₃ layer with the coating material at a thickness of 1 μm using UV-curing. Time taken for UV-curing was one minute, equipment employed for UV-curing was CURE ZONE HO2 (available from Daeho Glue Tech Ltd., Co.), and the UV-curing was carried out under conditions of wavelength of 365 nm and power of 120 mW/cm. In this case, a surface tension of the hydrophobic layer was 25.8 mN/m, a surface contact angle of DI water was 79.8°, and a surface contact angle of Formamide was 72.8°. Thereafter, polydimethylsiloxane (PDMS) material was contacted and cured with the hydrophobic layer, exposed to ultraviolet rays, and then separated from the hydrophobic layer, thereby achieving a patterned hydrophobic layer. For the patterned hydrophobic layer, its surface tension of was 7.29 mN/m, a surface contact angle of DI water was 122.6°, and a surface contact angle of Formamide was 110.2°. A water vapor permeability of the prepared film was 0.0624 g/m² day. FIG. 5 shows a process of forming a hydrophobic pattern layer according to Embodiment 1 and FIG. 6 is a schematic view showing a flexible gas barrier film with a hydrophobic pattern layer formed thereon according to Embodiment 1.

### Embodiment 2

In this embodiment, a flexible gas barrier film was prepared with the same process as Embodiment 1 except that a 300 nm-thick Al₂O₃ (purity: 99.99%) layer was deposited on both surfaces of a polyethersulfone (PES) substrate. A water vapor permeability of the prepared film was 0.00208 g/m² day.

### Embodiment 3

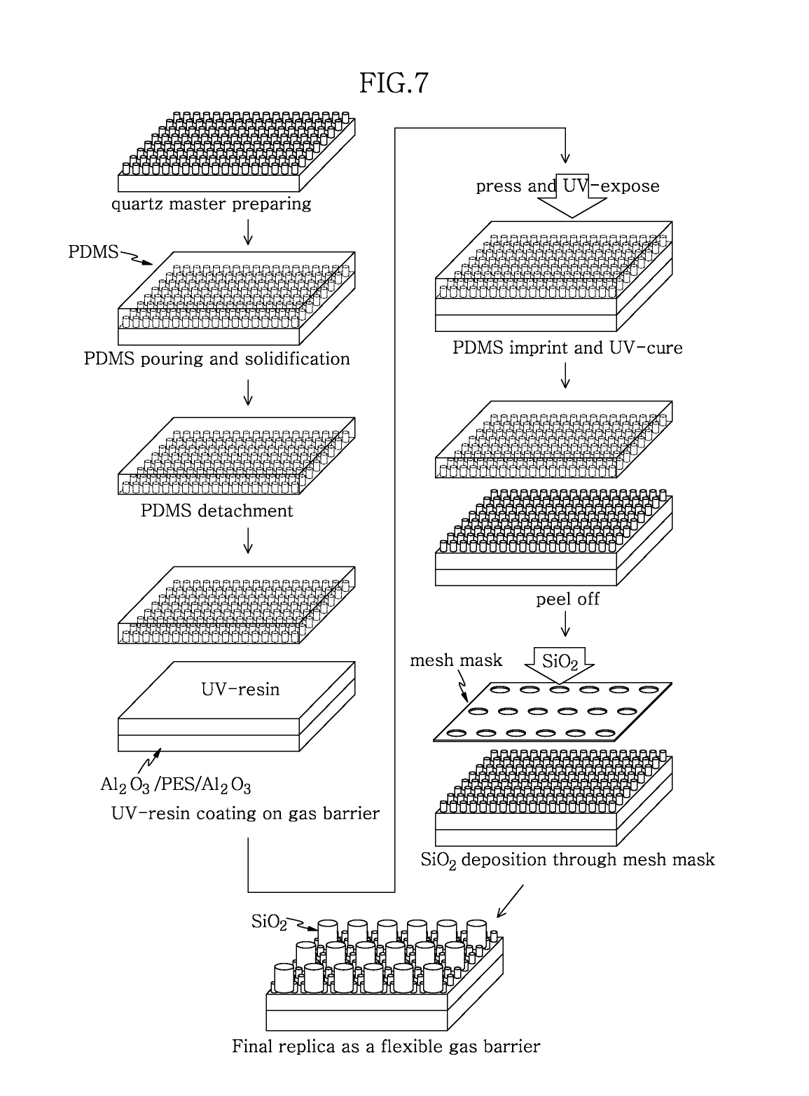

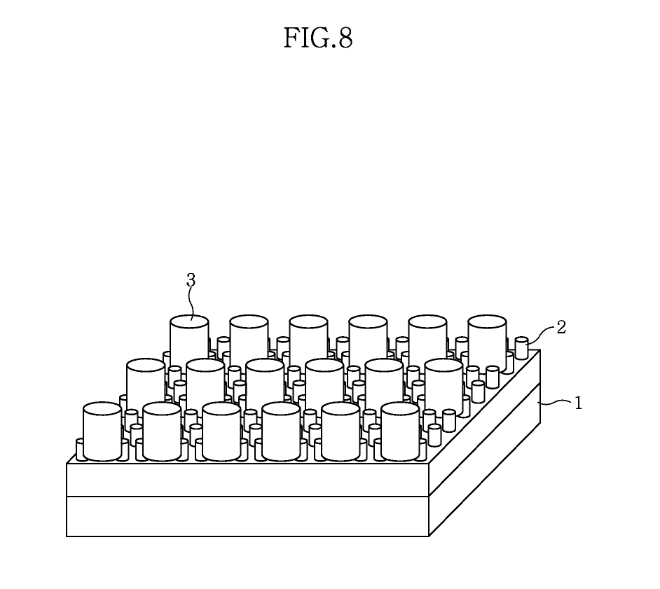

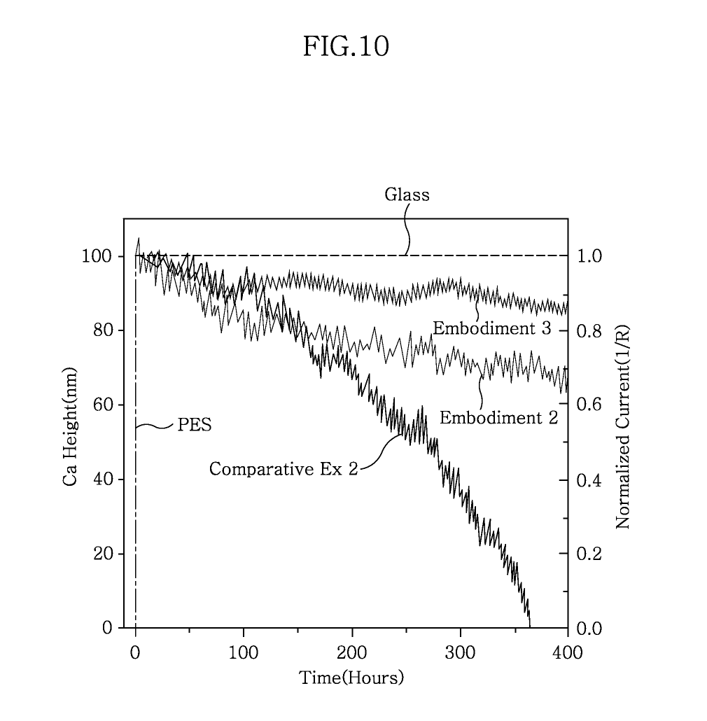

In this embodiment, a flexible gas barrier film was prepared with the same process as Embodiment 2 except that a 450 nm-thick SiO₂ (purity: 99.99%) layer was deposited on the hydrophobic pattern layer by E-beam evaporation using a stainless shadow mask. In this case, size of dots was set to 0.5 mm and a distance between centers of pattern was set to 1 mm. A surface tension of a hydrophilic pattern layer was 73.12 mN/m and surface contact angles of DI water and Formamide were less than 5°. A water vapor permeability of the prepared film was 0.000534 g/m² day. FIG. 7 shows a process of forming a hydrophilic pattern layer according to Embodiment 3 and FIG. 8 is a schematic view showing a flexible gas barrier film with a hydrophilic pattern layer formed thereon according to Embodiment 3. FIG. 10 shows comparison of water vapor permeability with time of Embodiments 2 and 3.

### COMPARATIVE EXAMPLE 1

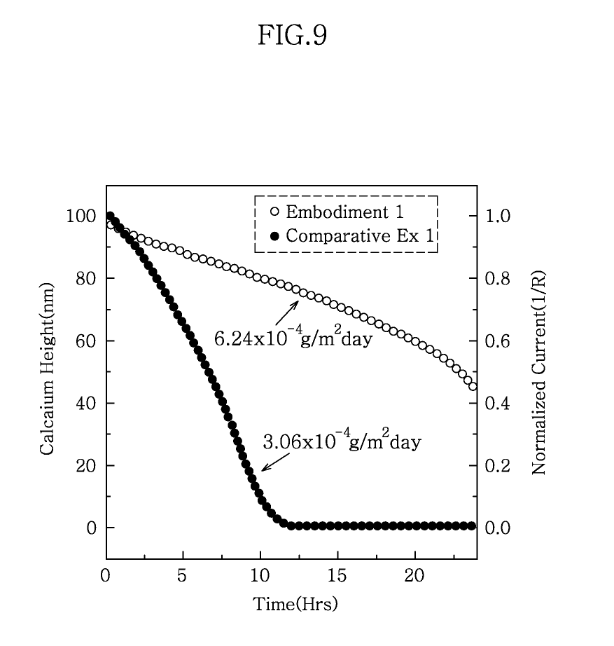

In this example, a flexible gas barrier film was prepared with the same process as Embodiment 1 except that a hydrophobic layer made of Multi-cure 984-LVF (available from DYMAC Ltd., Co.) was not patterned. A water vapor permeability of the prepared film was 0.306 g/m² day. FIG. 9 shows comparison of water vapor permeability with time of Embodiment 1 and Comparative Example 1.

### COMPARATIVE EXAMPLE 2

In this example, a flexible gas barrier film was prepared with the same process as Embodiment 2 except that a hydrophobic layer made of Multi-cure 984-LVF (available from DYMAC Ltd., Co.) was not patterned. A water vapor permeability of the prepared film was 0.0098 g/m² day.

### COMPARATIVE EXAMPLE 3

In this example, a flexible gas barrier film was prepared with the same process as Embodiment 1 except that a surface of a hydrophobic layer was subjected to a plasma treatment using CF₄ gas for further hydrophobicity. Hydrophobicity obtained by such a surface treatment did not lost long.

TABLE 1

| | | Water |
|---|---|---|
| | | Vapor |
| | | Perme- |
| | | ability |
| | Structure | (g/m² day) |
| Embodiment | PES(200 μm)/Al₂O₃(300 nm)/ | 0.0624 |
| 1 | Hydrophobic pattern layer | |
| Embodiment | Al₂O₃(300 nm)/PES(200 μm)/Al₂O₃(300 nm)/ | 0.00208 |
| 2 | Hydrophobic pattern layer | |
| Embodiment | Al₂O₃(300 nm)/PES(200 μm)/Al₂O₃(300 nm)/ | 0.000534 |
| 3 | Hydrophobic pattern layer/ | |
| | hydrophilic layer(450 nm) | |
| Comparative | PES(200 μm)/Al₂O₃(300 nm)/ | 0.306 |
| Ex 1 | Hydrophobic layer(1 μm) | |
| Comparative | Al₂O₃(300 nm)/PES(200 μm)/Al₂O₃(300 nm)/ | 0.0098 |
| Ex 2 | Hydrophobic layer(1 μm) | |
| Comparative | PES(200 μm)/Al₂O₃(300 nm)/ | — |
| Ex 3 | plasmarized Hydrophobic pattern layer(1 μm) | |

Table 1 shows that Embodiment 1 having the hydrophobic pattern layer has gas barrier ability superior to Comparative Example 1 having no hydrophobic pattern layer. Table 1 also shows that Embodiment 2 having the hydrophobic pattern layer has very low water vapor permeability. Table also shows that Embodiment 3 having the additional hydrophilic pattern layer has gas barrier ability superior to Embodiment 2 having the hydrophobic pattern layer only. However, Table 1 shows that Comparative Example 3 having the plasmarized hydrophobic layer does not last for hydrophobicity.

While the present invention has been particularly shown and described with reference to exemplary embodiments thereof, it will be understood by those skilled in the art that various changes in form and details may be made therein without departing from the spirit and scope of the present invention. The exemplary embodiments are provided for the purpose of illustrating the invention, not in a limitative sense. Thus, it is intended that the present invention covers the modifications and variations of this invention provided they come within the scope of the appended claims and their equivalents.

What is claimed is:

1. A flexible gas barrier film comprising:
a transparent base film; and
a hydrophobic pattern layer formed on the base film.

2. The flexible gas barrier film according to claim 1, wherein the hydrophobic pattern layer is made of polymer whose surface tension is 1 to 40 mN/m.

3. The flexible gas barrier film according to claim 1, wherein the hydrophobic pattern layer has an embossed pattern.

4. The flexible gas barrier film according to claim 3, wherein the hydrophobic pattern layer has a pattern width of 1 to 500 nm and a distance between centers of pattern is 0.1 to 10 times as large as the pattern width.

5. The flexible gas barrier film according to claim 1, wherein a water vapor permeability of the gas barrier film is less than 0.08 g/m² day.

6. The flexible gas barrier film according to claim 1, wherein a hydrophilic pattern layer is formed on the hydrophobic pattern layer.

7. The flexible gas barrier film according to claim 6, wherein the hydrophilic pattern layer is made of Si-based material whose surface tension is 70 to 100 mN/m.

8. The flexible gas barrier film according to claim 6, wherein the hydrophilic pattern layer has an embossed pattern.

9. The flexible gas barrier film according to claim 8, wherein the hydrophilic pattern layer is formed in discontinuity.

10. The flexible gas barrier film according to claim 8, wherein the hydrophilic pattern layer has a pattern width of 0.1 to 1 mm and a distance between centers of pattern is 0.1 to 10 times as large as the pattern width.

11. The flexible gas barrier film according to claim 6, wherein a water vapor permeability of the gas barrier film is less than 1×10⁻³ g/m2 day.

12. The flexible gas barrier film according to claim 1, wherein an inorganic layer made of oxide, nitride, carbide, oxy-nitride, oxy-carbide, nitro-carbide or oxy-nitro-carbide containing one or more metal selected from a group consisting of Si, Al, In, Sn, Zn, Ti, Cu, Ce and Ta is formed on at least one surface of the transparent base film.

13. The flexible gas barrier film according to claim 1, wherein the transparent base film is made of one or more selected from a group consisting of polyethylenenaphthalate, (meta)acrylate-based resin, polyester-based resin, styrene-based resin, transparent fluoro resin, polyimide-based resin, polyamide-based resin, polyetherimide-based resin, celluloseacylate-based resin, polyurethane resin, polyetheretherketone resin, polycarbonate resin, alicyclic polyolefine resin, polyalylate resin, polyethersulfone resin, polysulfone resin, cycloolefine copolymer, fluorene-ring modified polycarbonate resin, polyethylene and cyclic modified polycarbonate resin.

14. The flexible gas barrier film according to claim 2, wherein the hydrophobic pattern layer is made of one or more selected from a group consisting of acryl resin, perylene and melamine

15. The flexible gas barrier film according to claim 6, wherein the hydrophilic pattern layer is made of one selected from a group consisting of SiO₂, SiO and TiO₂.

16. A flexible displace device which uses a flexible gas barrier film according to claim 1 as a substrate.

17. The flexible displace device according to claim 16, wherein the hydrophobic pattern layer is made of polymer whose surface tension is 1 to 40 mN/m.

18. The flexible displace device according to claim 16, wherein the hydrophobic pattern layer has an embossed pattern.

19. The flexible displace device according to claim 16, wherein the hydrophobic pattern layer has a pattern width of 1 to 500 nm and a distance between centers of pattern is 0.1 to 10 times as large as the pattern width.

20. The flexible displace device according to claim 16, wherein a water vapor permeability of the gas barrier film is less than 0.08 g/m² day.

21. The flexible displace device according to claim 16, wherein a hydrophilic pattern layer is formed on the hydrophobic pattern layer.

22. The flexible displace device according to claim 21, wherein the hydrophilic pattern layer is made of Si-based material whose surface tension is 70 to 100 mN/m.

23. The flexible displace device according to claim 21, wherein the hydrophilic pattern layer has an embossed pattern.

24. The flexible displace device according to claim 23, wherein the hydrophilic pattern layer is formed in discontinuity.

25. The flexible displace device according to claim 23, wherein the hydrophilic pattern layer has a pattern width of 0.1 to 1 mm and a distance between centers of pattern is 0.1 to 10 times as large as the pattern width.

26. The flexible displace device according to claim 21, wherein a water vapor permeability of the gas barrier film is less than 1×10⁻³ g/m2 day.

27. The flexible displace device according to claim 16, wherein an inorganic layer made of oxide, nitride, carbide, oxy-nitride, oxy-carbide, nitro-carbide or oxy-nitro-carbide containing one or more metal selected from a group consisting of Si, Al, In, Sn, Zn, Ti, Cu, Ce and Ta is formed on at least one surface of the transparent base film.

28. The flexible displace device according to claim 16, wherein the transparent base film is made of one or more selected from a group consisting of polyethylenenaphthalate, (meta)acrylate-based resin, polyester-based resin, styrene-based resin, transparent fluoro resin, polyimide-based resin, polyamide-based resin, polyetherimide-based resin, celluloseacylate-based resin, polyurethane resin, polyetheretherketone resin, polycarbonate resin, alicyclic polyolefine resin, polyalylate resin, polyethersulfone resin, polysulfone resin, cycloolefine copolymer, fluorene-ring modified polycarbonate resin, polyethylene and cyclic modified polycarbonate resin.

29. The flexible displace device according to claim 17, wherein the hydrophobic pattern layer is made of one or more selected from a group consisting of acryl resin, perylene and melamine

30. A method for preparing a flexible gas barrier film, the method comprising:
forming a hydrophobic layer by coating or depositing polymer whose surface tension is 1 to 40 mN/m on a surface of a transparent base film; and
forming a hydrophobic pattern layer by patterning the hydrophobic layer.

31. The method according to claim 30, further comprising patterning a hydrophilic layer whose surface tension is 70 to 100 mN/m on the hydrophobic pattern layer.

32. The method according to claim 30, wherein the hydrophobic layer is patterned using ultraviolet imprinting, photolithography, micro contact printing, ink-jet printing, or screen printing

33. The method according to claim 31, wherein the hydrophilic layer is patterned using E-beam evaporation using a mask, sputtering, solution coating, thermal evaporation or printing.
